(19) United States
(12) Patent Application Publication
(10) Pub. No.: US 2015/0070856 A1
(43) Pub. Date: Mar. 12, 2015

(54) ELECTRONIC DEVICE

(71) Applicant: Kabushiki Kaisha Toshiba, Tokyo (JP)

(72) Inventors: Tomohiro Wada, Tachikawa-shi (JP); Kengo Kurose, Hamura-shi (JP); Shinichi Fujiwara, Hamura-shi (JP); Satoru Yasui, Kokubunji-shi (JP); Shigenori Miyagawa, Ome-shi (JP)

(21) Appl. No.: 14/297,440

(22) Filed: Jun. 5, 2014

(30) Foreign Application Priority Data
Sep. 11, 2013 (JP) 2013-188504

(51) Int. Cl. H05K 1/02

(52) U.S. Cl. CPC H05K 1/0281; H05K 2201/051
USPC 361/749

(57) ABSTRACT

According to one embodiment, an electronic device includes a component, a connector, a flexible printed circuit board and a tab. The component includes a first face, a second face, and an edge. The connector is configured to face the first face. The flexible printed circuit board includes a first portion configured to face the second face, a second portion configured to face the first face, a bent third portion between the first portion and the second portion and configured to face the edge, and a terminal provided to the second portion and configured to be connected to the connector. The tab includes an attachment portion and an extension portion. The extension portion is configured to be attached to the flexible printed circuit board. The extension portion extends from the attachment portion toward the terminal along the flexible printed circuit board.

### CROSS-REFERENCE TO RELATED APPLICATIONS

This application is based upon and claims the benefit of priority from Japanese Patent Application No. 2013-188504, filed Sep. 11, 2013, the entire contents of which are incorporated herein by reference.

### FIELD

Embodiments described herein relate generally to an electronic device.

### BACKGROUND

Electronic devices may comprise a flexible printed circuit board.

There is a risk that the flexible printed circuit board is damaged if, for example, the flexible printed circuit board is bent.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view illustrating a portable computer according to a first embodiment;

FIG. 2 is an exemplary plan view illustrating a part of a first portion in the first embodiment;

FIG. 3 is an exemplary sectional view illustrating a part of the first portion in the first embodiment;

FIG. 4 is an exemplary sectional view illustrating a part of a flexible printed circuit board (FPC) in the first embodiment;

FIG. 5 is an exemplary perspective view illustrating a connector to which the FPC is attached in the first embodiment;

FIG. 6 is an exemplary sectional view illustrating a part of a printed circuit board (PCB) and the FPC in the first embodiment;

FIG. 7 is an exemplary sectional view partially illustrating the PCB and the FPC that is inserted into the connector in the first embodiment;

FIG. 8 is an exemplary sectional view illustrating a PCB and an FPC according to a second embodiment;

FIG. 9 is an exemplary sectional view illustrating a PCB and an FPC according to a third embodiment; and

FIG. 10 is an exemplary sectional view partially illustrating the PCB and the FPC that is attached to a connector in the third embodiment.

### DETAILED DESCRIPTION

In general, according to one embodiment, an electronic device comprises a component, a connector, a flexible printed circuit board and a tab. The component comprises a first face, a second face opposite the first face, and an edge connecting the first face and the second face. The connector is configured to face the first face. The flexible printed circuit board comprises a first portion configured to face the second face, a second portion configured to face the first face, a bent third portion between the first portion and the second portion and configured to face the edge, and a terminal provided to the second portion and configured to be connected to the connector. The tab comprises an attachment portion and the extension portion. The attachment portion is configured to be attached to the flexible printed circuit board. The extension portion extends from the attachment portion toward the terminal along the flexible printed circuit board.

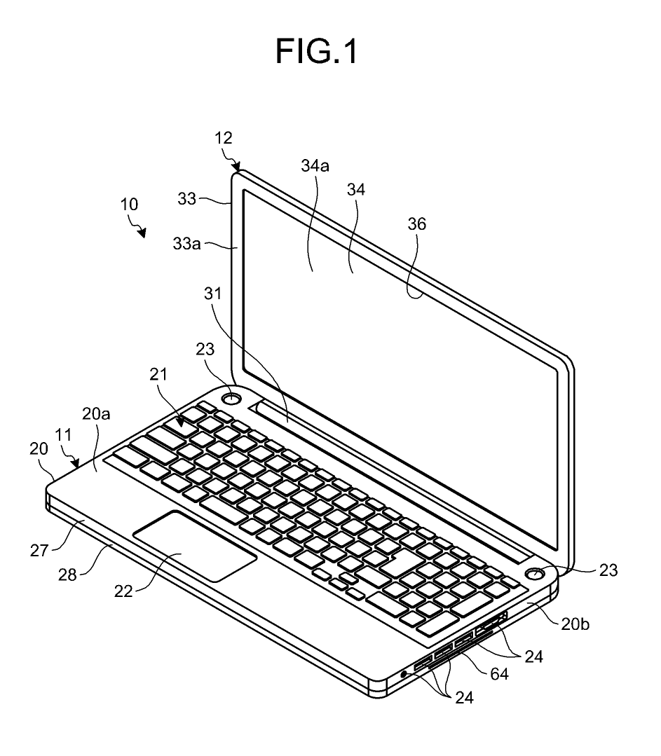

Hereinafter, described is a first embodiment with reference to FIG. 1 to FIG. 7. In the specification, basically, the user side is defined as the front side, the side farther from the user is defined as the rear side, the left side when viewed from the user is defined as the left direction, the right side when viewed from the user is defined as the right direction, the upper side when viewed from the user is defined as the upward direction, and the lower side when viewed from the user is defined as the downward direction. A plurality of expressions are made for constituent components according to the embodiment and description of the constituent components in some cases. Other expressions that are not described are not inhibited for the constituent components and the description thereof. Furthermore, other expressions are not inhibited for constituent components and description thereof for which a plurality of expressions are not made.

FIG. 1 is a perspective view illustrating a portable computer 10. The portable computer 10 is an example of an electronic device. Note that the electronic device is not limited to the portable computer 10, and may be various apparatuses such as personal computers, television receivers, tablet devices, recorders, printers, game machines, and car navigation systems.

As illustrated in FIG. 1, the portable computer 10 comprises a first portion 11 and a second portion 12. The first portion 11 can be also referred to as a unit, a module, a base, or a main body, for example. The second portion 12 can be also referred to as a unit, a module, a display, a monitor, or a displaying portion, for example.

The first portion 11 comprises a first housing 20, a keyboard 21, a touch pad 22, a pair of speakers 23, and a plurality of external connection connectors 24. The keyboard 21 and the touch pad 22 can be also referred to as input portions. The external connection connectors 24 can be also referred to as components or electronic components, for example.

The keyboard 21, the touch pad 22, and the speakers 23 are provided on an upper face 20a of the first housing 20. The keyboard 21, the touch pad 22, and the speakers 23 may be arranged on other places. The external connection connectors 24 are opened on a side face 20b of the first housing 20. The external connection connectors 24 are universal serial bus (USB) connectors, HDMI (registered trademark) output terminals, red-green-blue (RGB) connectors, and earphone jacks, for example.

The first housing 20 comprises a top cover 27 and a bottom cover 28. The top cover 27 is placed over the bottom cover 28 in the thickness direction and is attached to the bottom cover 28 with screws and craws, for example. The top cover 27 forms the upper face 20a of the first housing 20. The top cover 27 and the bottom cover 28 form the side face 20b of the first housing 20 in corporation.

The second portion 12 is attached to a rear end of the first portion 11 with a hinge 31. The second portion 12 can be moved rotationally with respect to the first portion 11 by approximately 180°, for example, between a closed position and an opened position. At the closed position, the second portion 12 is placed over the first portion 11 and the second portion 12 covers the upper face 20a of the first housing 20. At the opened position, the second portion 12 is aligned with the first portion 11 and the upper face 20a of the first housing 20 is exposed.

The second portion 12 comprises a second housing 33 and a display 34. The second housing 33 accommodates the display 34. A display opening 36 is provided on a front face 33a of the second housing 33. The display opening 36 may be closed by a transparent glass plate or acrylic plate, for example.

The display 34 is a liquid crystal display (LCD), for example. The display 34 is not limited thereto and may be another device that displays images, such as a plasma display, an organic electro luminescent (EL) display (GELD), or an electronic paper.

The display 34 comprises a screen 34a exposed through the display opening 36. The display 34 displays images on the screen 34a. Note that in the specification, examples of the images include still images, moving images, colors, and characters.

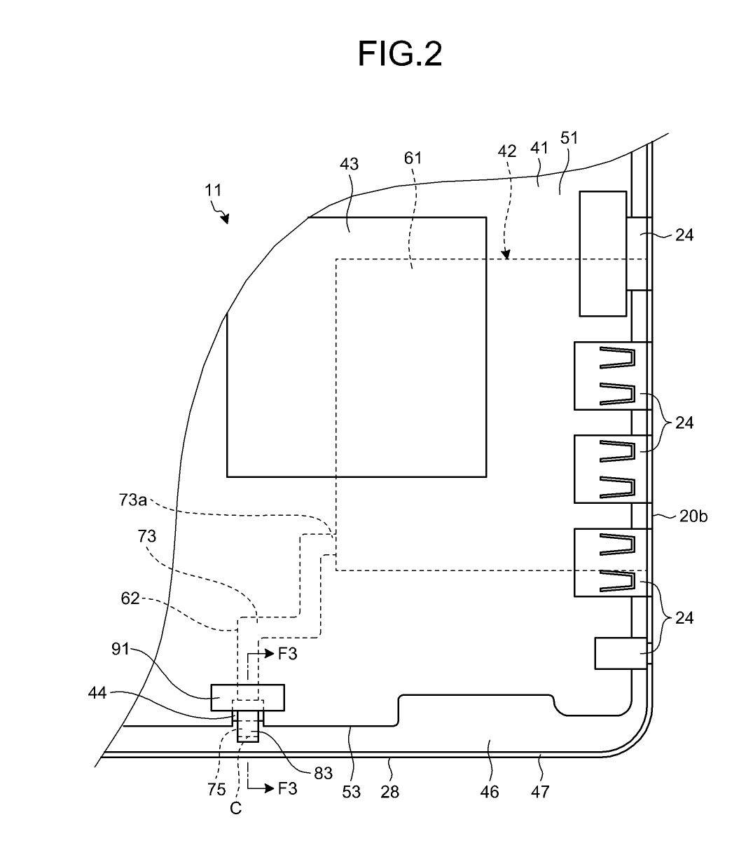

FIG. 2 is a plan view illustrating a part of the first portion 11 excluding the top cover 27. As illustrated in FIG. 2, the first portion 11 comprises a printed circuit board (hereinafter, referred to as PCB) 41, a smart card module 42, an integrated circuit (IC) 43, a connector 44, and various components such as a capacitor. The PCB 41 is an example of a component and can be also referred to as a wall, a plate, or a member, for example. The connector 44 can be also referred to as a component, an attachment portion, a connection portion, or a coupling portion, for example.

The bottom cover 28 comprises a bottom wall 46 and a side wall 47. Each of the bottom wall 46 and the side wall 47 can be also referred to as a wall, an outer shell, or apart of the housing, for example. The bottom wall 46 forms the bottom face of the first housing 20. The side wall 47 is erected from the peripheral edge of the bottom wall 46 so as to form a part of the side face 20b of the first housing 20.

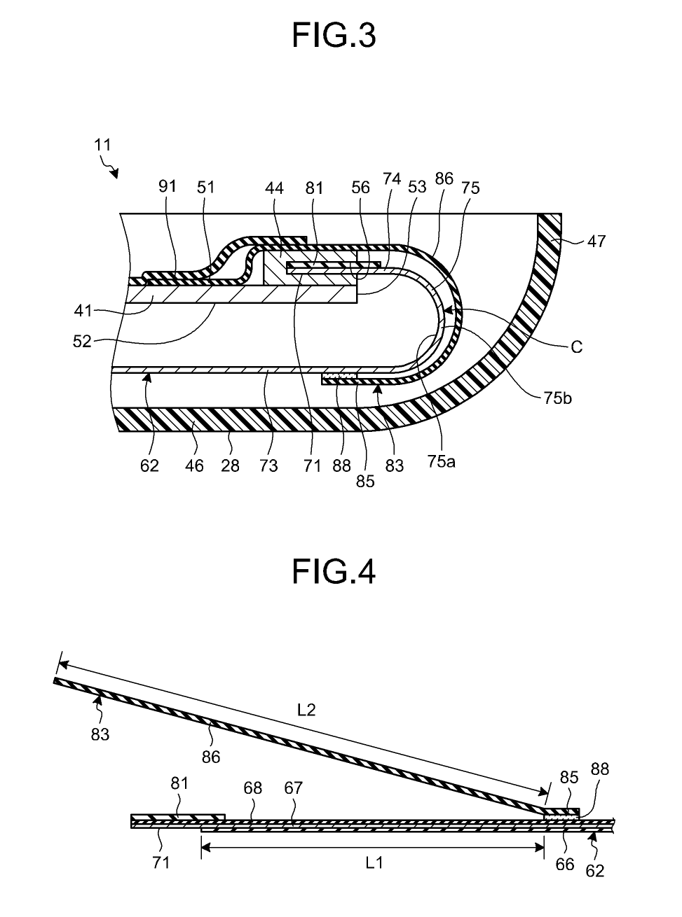

FIG. 3 is a sectional view illustrating a part of the first portion excluding the top cover 27, taken along line F3-F3 in FIG. 2. As illustrated in FIG. 3, the PCB 41 comprises an upper face 51, a lower face 52, and an edge 53. The upper face 51 is an example of a first face. The lower face 52 is an example of a second face and is located at the side opposite to the upper face 51. The edge 53 can be also referred to as a surface, a portion, an end, an intermediate portion, a coupling portion, or a connection portion, for example. The edge 53 connects the upper face 51 and the lower face 52.

The first housing 20 accommodates the PCB 41 and the smart card module 42. The PCB 41 and the smart card module 42 are located between the top cover 27 and the bottom cover 28. The PCB 41 is fixed to a boss provided on the bottom wall 46 by a screw, for example. The lower face 52 of the PCB 41 faces the bottom wall 46. The edge 53 faces the side wall 47.

As illustrated in FIG. 2, the external connection connectors 24, the IC 43, and the connector 44 are attached to the upper face 51 of the PCB 41. In other words, the connector 44 faces the upper face 51. It is to be noted that the connector 44 is not limited to be attached thereto and may be mounted on another substrate or a component that faces the upper face 51, for example.

As illustrated in FIG. 3, the connector 44 is closer to the edge 53 of the PCB 41. The connector 44 comprises an insertion portion 56. The insertion portion 56 is opened in the direction which the edge 53 faces to which the connector 44 is adjacent. That is to say, the insertion portion 56 is opened toward the side wall 47.

As illustrated in FIG. 2, the smart card module 42 comprises a reading and writing module 61 and a flexible printed circuit board (hereinafter, referred to as FPC) 62. The reading and writing module 61 can be also referred to as a component, an electronic component, a member, or a module, for example. The FPC 62 can be also referred to as a cable, a wiring, or a connection portion, for example. The “flexible printed circuit board” indicates a component in which an insulating layer having flexibility covers a conductive layer forming a wiring. Examples of the “flexible printed circuit board” include a flexible flat cable (FFC) and a flex-rigid printed circuit board (rigid flexible board).

The reading and writing module 61 is located between the PCB 41 and the bottom wall 46. That is to say, the smart card module 42 faces the lower face 52 of the PCB 41. For example, a smart card (IC card) is inserted into the reading and writing module 61 and the reading and writing module 61 inputs and outputs information to/from the smart card.

As illustrated in FIG. 1, a slot 64 is provided on the side face 20b of the first housing 20. The reading and writing module 61 is communicatively connected with the slot 64. The smart card is inserted into the reading and writing module 61 through the slot 64.

The FPC 62 connects the reading and writing module 61 and the connector 44 electrically. The FPC 62 is connected to the connector 44, so that the smart card module 42 is connected to the PCB 41 electrically.

FIG. 4 is a sectional view illustrating a part of the FPC 62. As illustrated in FIG. 4, the FPC 62 comprises a first insulating layer 66, a conductive layer 67, and a second insulating layer 68. In other drawings, the FPC 62 is illustrated in a simplified manner and the first insulating layer 66, the conductive layer 67, and the second insulating layer 68 are omitted.

The first and second insulating layers 66 and 68 are made of polyimide, for example. The conductive layer 67 is made of copper, for example. Each of the first insulating layer 66, the conductive layer 67, and the second insulating layer 68 may be made of another material. The conductive layer 67 is located between the first insulating layer 66 and the second insulating layer 68 so as to form a wiring.

A terminal 71 is provided on the end of the FPC 62. The terminal 71 is an example of a terminal and a first end and can be also referred to as a portion, a connection portion, an insertion portion, an engagement portion, a support portion, or a fitting portion, for example. The first insulating layer 66 is not provided on the terminal 71 and the terminal 71 is a portion on which the conductive layer 67 is exposed. The terminal 71 is inserted into the insertion portion 56 of the connector 44 so as to be connected to the connector 44 electrically. That is to say, the conductive layer 67 of the FPC 62 is connected to a conductive portion of the connector 44 electrically.

As illustrated in FIG. 3, the FPC 62 comprises a first portion 73, a second portion 74, and a third portion 75. The first portion 73 can be also referred to as a base portion, an extension portion, or a wiring portion, for example. The second portion 74 can be also referred to as an end, an end portion, an extension portion, or a wiring portion, for example. The third portion 75 is an example of a third portion and a bent section and can be also referred to as a bent portion, a curved portion, a bending portion, or a wraparound portion, for example.

The first portion 73 is a portion extending from the reading and writing module 61. That is, the first portion 73 faces the lower face 52 of the PCB 41. Abase end 73a of the first portion 73 is fixed to the reading and writing module 61. Note that the first portion 73 deforms elastically so as to be movable with respect to the PCB 41. The base end 73a of the first portion 73 is an example of a second end, and can be also referred to as a portion, a connected portion, a fixed portion, a supported portion, or an attached portion, for example.

As illustrated in FIG. 2, the first portion 73 extends from the reading and writing module 61 in the direction along the edge 53 to which the connector 44 is adjacent. The first portion 73 is bent perpendicularly at a plurality of places. A part of the first portion 73 that is the closest to the edge 53 to which the connector 44 is adjacent extends in the direction orthogonal to the edge 53. It is to be noted that the first portion 73 is not limited to extend in this manner and may extend from the reading and writing module 61 straight, for example.

As illustrated in FIG. 3, at least a part of the second portion 74 faces the upper face 51 of the PCB 41. The terminal 71 is provided on the second portion 74. With this, at least a part of the second portion 74 is inserted into the insertion portion 56 of the connector 44.

The third portion 75 is located between the first portion 73 and the second portion 74. The third portion 75 corresponds to a portion of the FPC 62 that is bent elliptically by approximately 180° in the thickness direction, for example. It is to be noted that the third portion 75 is not limited thereto. The third portion 75 warps around the edge 53 of the PCB 41 so as to connect the first portion 73 and the second portion 74.

The third portion 75 projects to the outer side relative to the edge 53 of the PCB 41 when viewed from the thickness direction of the PCB 41. In other words, the FPC 62 is installed around through places deviated from the upper face 51 and the lower face 52 of the PCB 41.

A center portion C of the third portion 75 corresponds to a portion that is the farthest from the PCB 41 when viewed from the thickness direction of the PCB 41. In other words, the center portion C of the third portion 75 corresponds to a top of the third portion 75 in the direction along the upper face 51 or the lower face 52 of the PCB 41.

The third portion 75 is closer to the terminal 71 rather than the base end 73a of the first portion 73. In other words, a distance between the center portion C of the third portion 75 and the terminal 71 is shorter than a distance between the center portion C of the third portion 75 and the base end 73a of the first portion 73.

The third portion 75 comprises an inner face 75a and an outer face 75b. The inner face 75a is a surface of the first insulating layer 66. The inner face 75a faces the edge 53. The outer face 75b is a front face of the second insulating layer 68 and is located at the side opposite to the inner face 75a. The outer face 75b faces the side wall 47. In other words, the third portion 75 is located between the edge 53 of the PCB 41 and the side wall 47 of the bottom cover 28.

A reinforcing plate 81 is attached to the terminal 71 of the FPC 62. The reinforcing plate 81 is an example of a reinforcing member, and can be also referred to as a rigid member, a spacer, a bonded member, or a member, for example. The reinforcing plate 81 is made of polyimide, for example.

As illustrated in FIG. 4, the reinforcing plate 81 is bonded to the second insulating layer 68 with an adhesive, for example. In other words, as illustrated in FIG. 3, the reinforcing plate 81 is bonded to the outer face of a portion of the second portion 74 on which the terminal 71 is provided. The reinforcing plate 81 is inserted into the insertion portion 56 of the connector 44 together with the terminal 71.

A tab 83 is attached to the FPC 62. The tab 83 can be also referred to as a member, a component, a pulling portion, a guide portion, a covering portion, or a protection portion, for example. The tab 83 is made of polyimide like the first and second insulating layers 66 and 68, for example, and is a tape having elasticity. It is to be noted that the tab 83 is not limited thereto and may be made of another material.

The tab 83 comprises an attachment portion 85 and an extension portion 86. The attachment portion 85 can be also referred to as an adhered portion, a fixed portion, or an end portion, for example. The extension portion 86 can be also referred to as a free portion, a pulled portion, a guide portion, an operated portion, a bolded portion, a protection portion, a covering portion, a bent portion, or a curved portion, for example.

The attachment portion 85 corresponds to an end portion of the tab 83, for example. The attachment portion 85 is attached to the outer face of the first portion 73 that faces the bottom wall 46 with an adhesive 88, for example. That is to say, the attachment portion 85 is attached to the second insulating layer 68. In other words, the attachment portion 85 is bonded to the FPC 62 between the center portion C of the third portion 75 and the base end 73a of the first portion 73.

The attachment portion 85 is separated from the reinforcing plate 81. The third portion 75 that is bent and wraps around the edge 53 is formed between the terminal 71 to which the reinforcing plate 81 is attached and a portion of the FPC 62 to which the attachment portion 85 is attached.

The portion of the first portion 73 to which the attachment portion 85 is attached is separated from the third portion 75. That is to say, the attachment portion 85 is attached to a portion of the FPC 62 that is separated from the bent portion thereof. It is to be noted that the portion of the first portion 73 to which the attachment portion 85 is attached may be bent. In this case, a curvature radius of the third portion 75 is smaller than a curvature radius of the portion of the first portion 73 to which the attachment portion 85 is attached.

In another expression, the attachment portion 85 is attached to the portion of the FPC 62 that is deviated from the bent portion facing the edge 53. In still another expression, the attachment portion 85 is attached to the portion of the PCB 41 deviated from the portion that is the farthest from the edge 53 in the direction in which the edge 53 is directed.

The extension portion 86 extends from the attachment portion 85 to the terminal 71 side. As illustrated in FIG. 4, the extension portion 86 extends from the attachment portion 85 toward the terminal 71 of the FPC 62 along the FPC 62. It is to be noted that the extension portion 86 may extend in the direction intersecting with the FPC 62 partially. That is to say, the extension portion 86 may be bent.

The FPC 62 ahead of the attachment portion 85 is shorter than the tab 83. That is to say, a length L1 from the portion of the FPC 62 to which the attachment portion 85 is attached to the terminal 71 is smaller than a length L2 from the attachment portion 85 to the end of the extension portion 86 of the tab 83. It is to be noted that the length L1 of the FPC 62 may be larger than the length L2 of the tab 83.

As illustrated in FIG. 3, the extension portion 86 of the tab 83 is bent by approximately 180° along the third portion 75 of the FPC 62. The extension portion 86 covers the outer face 75b of the third portion 75. Furthermore, the extension portion 86 covers the second portion 74 and the connector 44.

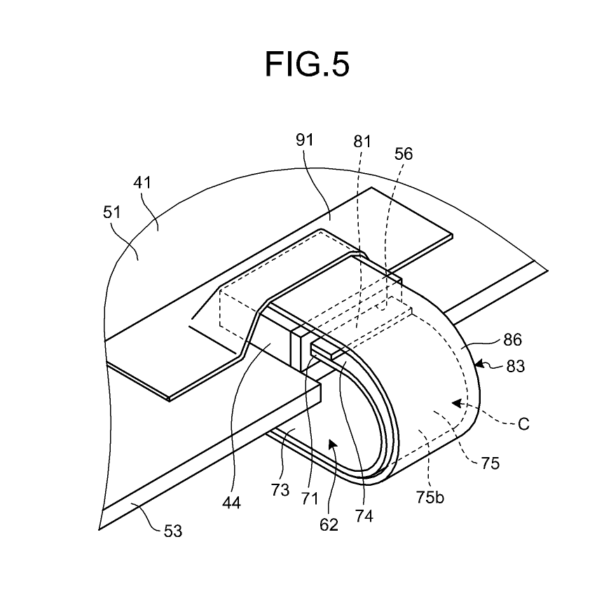

FIG. 5 is a perspective view illustrating the connector 44 to which the FPC 62 is attached. As illustrated in FIG. 5, the extension portion 86 of the tab 83 is fixed to the upper face 51 of the PCB 41 by a tape 91, for example. It is to be noted that the extension portion 86 is not limited to be fixed in this manner and may be fixed to the PCB 41 by being hooked on a claw or by being inserted into a hole, for example.

Hereinafter, described is an example of a method of attaching the FPC 62 to the connector 44. It is to be noted that the method of attaching the FPC 62 to the connector 44 is not limited to that as will be described below.

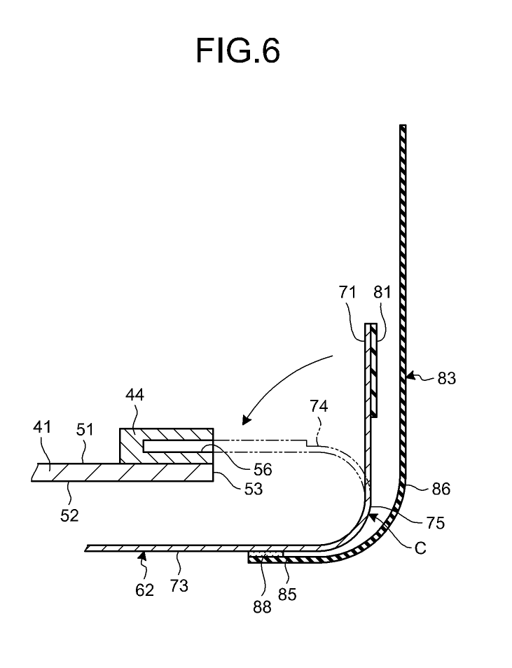

FIG. 6 is a sectional view illustrating a part of the PCB 41 and the FPC 62. As indicated by two-dotted lines in FIG. 6, the FPC 62 extending along the lower face 52 of the PCB 41 is bent by approximately 180°. With this, a part of the FPC 62 is curved and the third portion 75 is formed.

The FPC 62 has elasticity, so that the FPC 62 generates a repulsion force of trying to return to the straight state if it is bent. The FPC 62 is bent by being pressed by the tab 83 held by an operator, for example. That is to say, the operator can press the FPC 62 through the tab 83. It is to be noted that the FPC 62 may be bent by being held by the operator directly.

The terminal 71 of the bent FPC 62 is set to the insertion portion 56 of the connector 44. In other words, the front end of the FPC 62 is hooked by the insertion portion 56. In this case, the terminal 71 may be inserted into the insertion portion 56 partially.

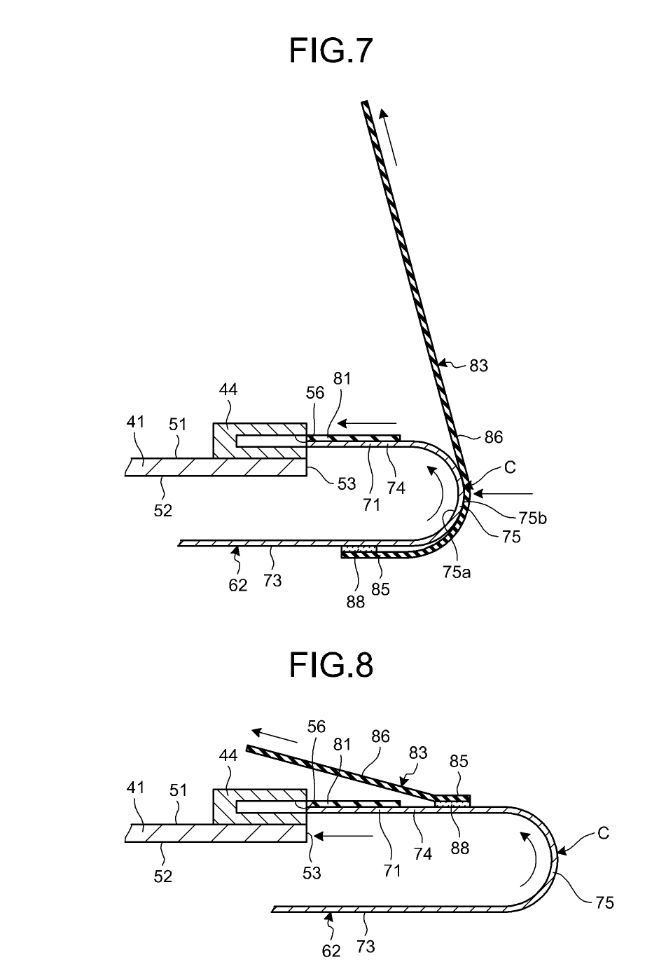

FIG. 7 is a sectional view partially illustrating the PCB 41 and the FPC 62 that is inserted into the connector 44. As indicated by an arrow in FIG. 7, the operator pulls the extension portion 86 of the tab 83, for example. With this, the extension portion 86 presses the outer face 75b of the third portion 75 toward the insertion portion 56 of the connector 44. Furthermore, the FPC 62 pulled by the tab 83 is fed out, so that the terminal 71 located at the end of the FPC 62 advances into the insertion portion 56 of the connector 44. This causes the terminal 71 to be inserted into the insertion portion 56.

The tab 83 may be pulled while pressing the FPC 62 that tries to return to the straight state by the repulsion force. That is to say, the tab 83 is used for guiding the terminal 71 of the FPC 62 to the insertion portion 56 of the connector 44.

When the terminal 71 of the FPC 62 is inserted into the insertion portion 56 of the connector 44, the extension portion 86 covers the second portion 74, the third portion 75, and the connector 44. In this state, the extension portion 86 is fixed to the PCB 41 by the tape 91. With the above-mentioned operations, the FPC 62 is attached to the connector 44.

In the portable computer 10 according to the first embodiment, the attachment portion 85 of the tab 83 is attached to the first portion 73. The portion of the FPC 62 to which the attachment portion 85 is attached is made thicker by the tab 83 so as to be hardened. The portion to which the attachment portion 85 is attached is provided not on the third portion 75 that is bent but on the first portion 73. This can suppress generation of stress concentration due to the bending of the FPC 62 on an end of the portion to which the attachment portion 85 is attached (boundary portion of the FPC 62 between a region to which the attachment portion 85 is attached and another region).

The extension portion 86 of the tab 83 extends toward the terminal 71 from the attachment portion 85. With this, when the FPC 62 is attached to the connector 44, for example, steep bending of the FPC 62 and generation of stress concentration due to it can be suppressed. This can suppress damage of the FPC 62 due to the stress concentration.

As the distance between the attachment portion 85 and the terminal 71 as the portion on which the FPC 62 is supported by the connector 44 is smaller, there may arise a higher risk that stress concentration is easy to be generated on the end of the portion of the FPC 62 to which the attachment portion 85 is attached. For coping with this, the attachment portion 85 is fixed to the FPC 62 between the center portion C of the third portion 75 and the base end 73a of the first portion 73 which is a position farther from the second portion 74 on which the terminal 71 is provided. To be more specific, the attachment portion 85 is attached to the first portion 73.

The tab 83 is attached to the FPC 62 at the position farther from the terminal 71, so that a portion of the FPC 62 between the attachment portion 85 and the terminal 71 is easy to be deformed elastically when the tab 83 is operated for attaching the terminal 71 to the connector 44. A force is released by the elastic deformation and stress is difficult to be concentrated on a local place of the FPC 62. This can suppress damage of the FPC 62 due to the stress concentration.

The attachment portion 85 of the tab 83 is attached to the FPC 62 at a position farther from the reinforcing plate 81. With this, when the tab 83 is operated, stress concentration on the end of the portion of the FPC 62 to which the reinforcing plate 81 is attached can be suppressed. This can suppress damage of the FPC 62.

The length L2 of the extension portion 86 of the tab 83 is larger than the length L1 of the FPC 62 from the attachment portion 85 to the terminal 71. With this, the tab 83 can press the FPC 62 so as to guide the terminal 71 to the connector 44. This can prevent the operator from touching the FPC 62 directly and prevent scratches and contaminants from being generated on the FPC 62, for example.

The extension portion 86 of the tab 83 covers the third portion 75 of the FPC 62. With this, generation of scratches and contaminants on the third portion 75 of the FPC 62 due to scrape against other components can be suppressed, for example. This can suppress damage of the FPC 62.

The extension portion 86 of the tab 83 covers the outer face 75b of the third portion 75. With this, the extension portion 86 can press the outer face 75b of the third portion 75, so that the FPC 62 is attached to the connector 44 by the tab 83 easily.

The extension portion 86 of the tab 83 is fixed to the PCB 41 by the tape 91. With this, separation of the tab 83 from the third portion 75 due to an elastic force of the tab 83 can be suppressed, for example.

The attachment portion 85 of the tab 83 is separated from the third portion 75 that is bent. With this, stress concentration on the end of the portion of the FPC 62 to which the attachment portion 85 is attached due to the bending can be further suppressed.

The first portion 73 is movable with respect to the PCB 41, so that the FPC 62 can be moved when the tab 83 is operated. With this, a force is released by the movement and stress is difficult to be concentrated on a local place of the FPC 62. This can suppress damage of the FPC 62 due to the stress concentration.

It is to be noted that the attachment portion 85 is not limited to be attached to the first portion 73 and may be attached to another place. For example, the attachment portion 85 may be attached to the third portion 75. The attachment portion 85 is attached between the center portion C of the third portion 75 and the first portion 73, for example.

Hereinafter, described is a second embodiment with reference to FIG. 8. In description of the following plurality of embodiments, reference numerals same as those of the constituent components that have been already described denote constituent components having the same or similar functions as those of the constituent components that have been already described and overlapped explanation thereof is omitted in some cases. In addition, all the functions and characteristics of the plurality of constituent components denoted with the same reference numerals are not necessarily common and the constituent components may have different functions and characteristics in accordance with the respective embodiments.

FIG. 8 is a sectional view illustrating the PCB 41 and the FPC 62 according to the second embodiment. As illustrated in FIG. 8, the attachment portion 85 in the second embodiment is attached to the second portion 74 of the FPC 62. The attachment portion 85 is separated from the reinforcing plate 81. The extension portion 86 extends from the attachment portion 85 in the direction toward the terminal 71 along the FPC 62.

When the FPC 62 is attached to the connector 44, the operator pulls the extension portion 86 of the tab 83, for example. With this, the extension portion 86 pulls the second portion 74 on which the terminal 71 is provided toward the insertion portion 56 of the connector 44. This causes the terminal 71 to be inserted into the insertion portion 56.

With the portable computer 10 in the second embodiment, the attachment portion 85 is attached to the second portion 74 of the FPC 62. With this, a force of pulling the tab 83 is easy to be transferred to the terminal 71. This makes it possible to attach the terminal 71 to the connector 44 more stably.

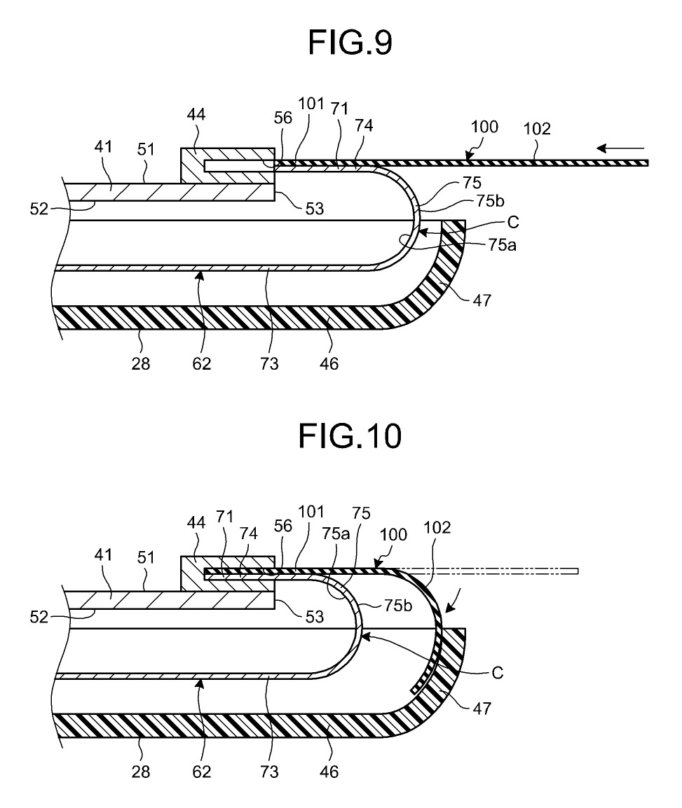

Hereinafter, described is a third embodiment with reference to FIG. 9 and FIG. 10. FIG. 9 is a sectional view illustrating the PCB 41 and the FPC 62 according to the third embodiment. In third embodiment, a tab 100 instead of the reinforcing plate 81 and the tab 83 is attached to the FPC 62. The tab 100 is an example of a tab.

As illustrated in FIG. 9, the tab 100 comprises an attachment portion 101 and an extension portion 102. The attachment portion 101 is attached to a portion of the second portion 74 on which the terminal 71 is provided with an adhesive, for example. The attachment portion 101 is attached to the second portion 74 at a position separated from the third portion 75. The attachment portion 101 is inserted into the insertion portion 56 of the connector 44 together with the terminal 71. The extension portion 102 extends from the attachment portion 101 in the direction toward the third portion 75 along the FPC 62.

When the FPC 62 is attached to the connector 44, the operator presses the extension portion 102 of the tab 100, for example. With this, the extension portion 102 presses the second portion 74 on which the terminal 71 is provided toward the insertion portion 56 of the connector 44. This causes the terminal 71 to be inserted into the insertion portion 56.

FIG. 10 is a sectional view partially illustrating the PCB 41 and the FPC 62 attached to the connector 44. As illustrated in FIG. 10, when the FPC 62 is attached to the connector 44, the extension portion 102 is bent along the third portion 75. The bent extension portion 102 is made contact with the inner face of the side wall 47 of the bottom cover 28.

The extension portion 102 is fixed to the side wall 47 while being pressed by the side wall 47. The extension portion 102 may be fixed to the side wall 47 by being hooked on a claw or being inserted into a hole, for example. Furthermore, the extension portion 102 may be fixed to the bottom wall 46 or another component. The extension portion 102 that has been bent and fixed covers the outer face 75b of the third portion 75 of the FPC 62.

With the portable computer 10 in the third embodiment, the attachment portion 101 of the tab 100 is attached to the second portion 74. With this, generation of stress concentration on the end of the portion to which the attachment portion 101 is attached due to the bending of the FPC 62 can be suppressed. This can suppress damage of the FPC 62 due to the stress concentration.

Furthermore, the extension portion 102 covers the third portion 75. With this, generation of scratches and contaminants on the third portion 75 of the FPC 62 due to scrape against other components can be suppressed, for example. This can suppress damage of the FPC 62.

The extension portion 102 of the tab 100 extends from the attachment portion 101 in the direction toward the third portion 75. The operator presses the extension portion 102, so that the terminal 71 is attached to the connector 44 more easily.

According to at least one of the above-mentioned embodiments, the attachment portion of the tab is attached not to the third portion of the flexible printed circuit board that is bent but to the first portion facing the first face of the component or the second portion facing the second face of the component. This can suppress damage of the flexible printed circuit board.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the component is not limited to the PCB 41 and may be an optical disk drive (ODD), a part of the housing, or the like. In addition, the FPC 62 is not limited to be formed as a part of the smart card module 42 and may be formed as a part of another component or may be provided independently. The FPC 62 may be wired between two housings so as to connect a component accommodated in one housing and another component in the other housing, for example.

The extension portion 86 of the tab 83 and the extension portion 102 of the tab 100 may cover the inner face 75a of the third portion 75. In other words, the extension portions 86 and 102 may be located between the edge 53 and the third portion 75 so as to prevent the third portion 75 from making contact with the edge 53, for example.

What is claimed is:

1. An electronic device comprising:
a component comprising a first face, a second face opposite the first face, and an edge connecting the first face and the second face;
a connector configured to face the first face;
a flexible printed circuit board comprising a first portion configured to face the second face, a second portion configured to face the first face, a bent third portion between the first portion and the second portion and configured to face the edge, and a terminal provided to the second portion and configured to be connected to the connector; and
a tab comprising an attachment portion and an extension portion, the attachment portion configured to be attached to the flexible printed circuit board, the extension portion extending from the attachment portion toward the terminal along the flexible printed circuit board.

2. The electronic device of claim 1, wherein the attachment portion is configured to be attached to the first portion.

3. The electronic device of claim 2, further comprising a reinforcing member configured to be attached to the terminal at a position separated from the attachment portion and configured to be attached to the connector together with the terminal.

4. The electronic device of claim 2, wherein a length of the flexible printed circuit board between a portion at which the attachment portion of the tab is attached and the terminal is shorter than a length of the tab between the attachment portion and an end of the extension portion.

5. The electronic device of claim 4, wherein the extension portion is configured to be bent along the third portion and to cover the third portion.

6. The electronic device of claim 5, wherein
the third portion comprises an inner face configured to face the edge and an outer face opposite the inner face, and
the extension portion configured to cover the outer face of the third portion.

7. The electronic device of claim 6, wherein the extension portion is configured to be fixed to the component.

8. The electronic device of claim 1, wherein a portion of the first portion to which the attachment portion is attached is separated from the third portion.

9. The electronic device of claim 2, wherein the first portion is movable with respect to the component.

10. An electronic device comprising:
a component comprising a first face, a second face opposite the first face, and an edge connecting the first face and the second face;
a connector configured to face the first face;
a flexible printed circuit board comprising a first portion configured to face the second face, a second portion configured to face the first face, a bent third portion between the first portion and the second portion and configured to face the edge, and a terminal provided to the second portion and configured to be connected to the connector; and
a tab comprising an attachment portion and an extension portion, the attachment portion configured to be attached to the first portion or the second portion, the extension portion extending from the attachment portion along the flexible printed circuit board and configured to cover the third portion.

11. An electronic device comprising:
a housing;
a connector in the housing;
a flexible printed circuit board in the housing and comprising a first end configured to be attached to the connector, a second end opposite the first end, and a bent section bent in a thickness direction of the flexible printed circuit board; and
a tab configured to be connected to the flexible printed circuit board between a center portion of the bent section and the second end.

12. The electronic device of claim 11, wherein the bent section is closer to the first end than the second end.
